(19) United States
(12) Patent Application Publication
(10) Pub. No.: US 2025/0112043 A1
(43) Pub. Date: Apr. 3, 2025

(54) LOW ENERGY TREATMENT TO PASSIVATE SiC SUBSTRATE DEFECTS

(71) Applicant: Applied Materials, Inc., Santa Clara, CA (US)

(72) Inventors: Vikram M. BHOSLE, North Reading, MA (US); Hans-Joachim L. GOSSMANN, Summit, NJ (US); Stephen E. KRAUSE, Ipswich, MA (US); Deven Raj MITTAL, Middleton, MA (US); Hiroyuki ITO, Narita (JP)

(73) Assignee: Applied Materials, Inc., Santa Clara, CA (US)

(21) Appl. No.: 18/391,541

(22) Filed: Dec. 20, 2023

Related U.S. Application Data
(60) Provisional application No. 63/587,398, filed on Oct. 2, 2023.

(51) Int. Cl. H01L 21/02; C23C 14/48; C30B 25/18; C30B 29/68; C30B 31/06; C30B 31/22; H01J 37/32; H01L 21/67

(52) U.S. Cl. CPC H01L 21/02658; C23C 14/48; C30B 25/186; C30B 29/68; C30B 31/06; C30B 31/22; H01J 37/3244; H01L 21/02378; H01L 21/67213; H01J 2237/3365

(57) ABSTRACT

Disclosed herein are methods for passivating SiC substrate defects using a low-energy treatment. In some embodiments, a method may include providing a silicon carbide (SIC) substrate, treating the SiC substrate using an ion implant or a plasma doping process, forming a first epitaxial layer over an upper surface of the SiC substrate after the SiC substrate is treated, and forming a second epitaxial layer over the first epitaxial layer.

### CROSS-REFERENCE TO RELATED APPLICATIONS

This application claims priority to U.S. provisional patent application Ser. No. 63/587,398, filed Oct. 2, 2023, the entire contents of which is incorporated by reference herein.

### FIELD OF THE DISCLOSURE

The present embodiments relate to semiconductor device patterning, and more particularly, to forming transistors using a low-energy treatment for SiC substrates.

### BACKGROUND OF THE DISCLOSURE

SiC substrates and epitaxial (epi) wafers contain many forms of defects, including point defects, stacking faults (e.g., Shockley stacking fault (SSF)), and various types of dislocations. These dislocations may include basal plane dislocation (BPD), threading edge dislocation (TED), and threading screw dislocation (TSD). During epi layer growth, the threading dislocations in the substrate tend to make their way into the epi layer. Some threading screw dislocations convert to Frank-type stacking faults, and some to stacking fault complexes.

Stacking faults are a concern because they impair device performance and reliability. BPD is particularly concerning, as these defects can propagate into the epi layer, where they are transformed into Shockley-type stacking faults or threading edge dislocations. The former often causes severe degradation in bipolar devices.

Accordingly, improved approaches for mitigating stacking faults in epi layers are desirable.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include providing a silicon carbide (SiC) substrate, treating the SiC substrate using an ion implant or a plasma doping process, forming a first epitaxial layer over an upper surface of the SiC substrate after the SiC substrate is treated, and forming a second epitaxial layer over the first epitaxial layer.

In another aspect, a method of forming a silicon carbide (SiC) device may include providing a SiC substrate, treating the SiC substrate using an ion implant or a plasma doping process, epitaxially forming a n⁻ layer over an upper surface of the SiC substrate after the SiC substrate is treated, and epitaxially forming a p+ layer over the n⁻ layer.

In yet another aspect, a method of forming a silicon carbide (SiC) pin diode may include providing a SiC substrate, treating the SiC substrate using an ion implant or a plasma doping process, epitaxially forming a n⁻ layer over an upper surface of the SiC substrate after the SiC substrate is treated, and epitaxially forming a p+ layer directly atop the n layer.

In still yet another aspect, a system for forming a silicon carbide (SiC) device may include a first processing chamber comprising an ion implanter or a plasma doping tool operable to treat a SiC substrate, and a second processing chamber operable to: epitaxially form an layer over an upper surface of the SiC substrate after the SiC substrate is treated; and epitaxially form a p+ layer over the n⁻ layer.

### BRIEF DESCRIPTION OF THE DRAWINGS

The accompanying drawings illustrate exemplary approaches of the disclosure, including the practical application of the principles thereof, as follows:

FIG. 1 is a side cross-sectional view of a treatment process to a SiC substrate of a device, according to embodiments of the present disclosure;

FIG. 2 is a side cross-sectional view of a first epitaxial layer formed over the SiC substrate, according to embodiments of the present disclosure;

FIG. 3 is a side cross-sectional view of the device during an optional treatment process, according to embodiments of the present disclosure;

FIG. 4 is a side cross-sectional view of a second epitaxial layer formed over the first epitaxial layer, according to embodiments of the present disclosure;

FIG. 5 is a side cross-sectional view of the device during an optional treatment process, according to embodiments of the present disclosure;

FIG. 6 illustrates a schematic diagram of a processing apparatus according to embodiments of the present disclosure;

FIG. 7 is a plasma doping system, according to embodiments of the present disclosure; and

FIG. 8 illustrates a schematic diagram of another processing apparatus according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods in accordance with the present disclosure will now be described more fully hereinafter with reference to the accompanying drawings, where various embodiments are shown. The methods may be embodied in many different forms and are not to be construed as being limited to the embodiments set forth herein. Instead, these embodiments are provided so the disclosure will be thorough and complete, and will fully convey the scope of the methods to those skilled in the art.

As will be described herein, embodiments of the disclosure address the drawbacks of the prior art identified above by treating a SiC substrate, prior to formation of one or more epitaxial layers atop the substrate, using an ion implant or a plasma doping process to prevent SSF formation and expansion (i.e., propagation in epi layer) by passivating BPD and partial dislocations (i.e., dangling bonds) near the SiC surface. The treatment process may further inhibit e-h recombination at the interface of the SiC substrate and the one or more epitaxial layers, which prevents recombination enhanced dislocation glide. That is, because the dangling bond is passivated, there is no site for e-h recombination.

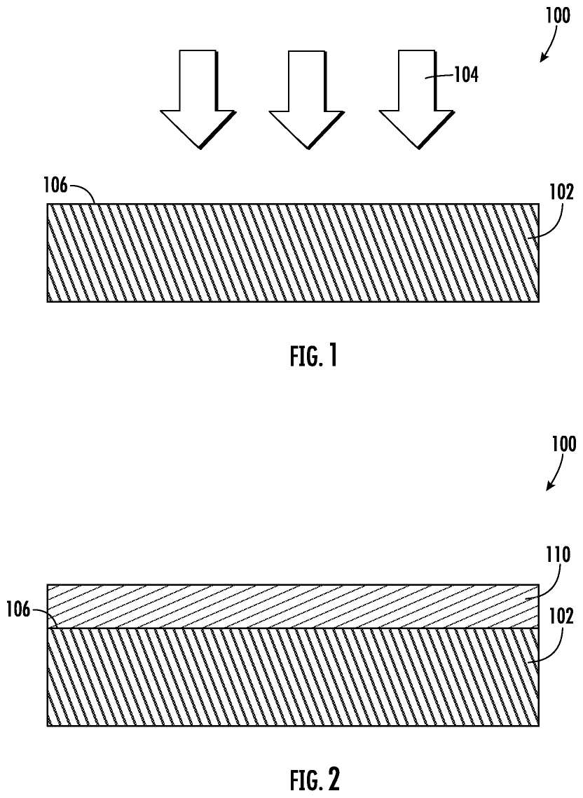

FIG. 1 is a side cross-sectional view of an example device 100 at an early stage of processing. In one non-limiting embodiment, the device 100 may be a SiC pin diode. The device 100 may include a substrate 102, such as a silicon carbide (SiC) n⁺ layer. In other non-limiting embodiments, the substrate 102 may be a silicon carbonitride (SiCN) substrate, a silicon carbonoxide (SiCO), an epi substrate, a silicon-on-insulator (SOI) substrate, a carbon doped oxide, or a silicon nitride. The substrate 102 may be a planar substrate or a patterned substrate.

As further shown in FIG. 1, a first treatment process 104 may be performed to the substrate 102. More specifically, the first treatment process 104 may be applied to an upper surface 106 of the substrate 102. Although non-limiting, the first treatment process 104 may be an ion implant including one or more beamline implants delivered at a pre-defined angle, a predefined energy, a predefined dose, etc. For example, one or more implantation ion species, (e.g., hydrogen) can be used during the ion implant. In some embodiments, the ion implant is performed at room temperature (e.g., 15-40°) or at a high temperature (e.g., 40-600° C.), and with a high dose (e.g., between 5E16 and 7E16). More specifically, the ion implant may be performed while the substrate 102 is held at the room temperature or at the high temperature. Because the first treatment process 104 is performed to the exposed upper surface 106 of the substrate 102, the implant energy can be low, e.g., 100 keV or less. In the embodiment shown, the ion implant may be delivered perpendicular to the upper surface 106 of the substrate 102. In other embodiments, the ion implant may be delivered to the substrate 102 at a non-zero angle relative to a perpendicular extending from the upper surface 106 of the substrate 102.

In other examples, the first treatment process 104 may be a plasma treatment, e.g., plasma doping (PLAD) or a decoupled plasma treatment (DPX), which impacts the substrate 102. This plasma doping may be performed at a high temperature (e.g., 40-600° C.) or at room temperature (e.g., 15-40°). More specifically, the plasma doping may be performed while the substrate 102 is held at the room temperature or at the high temperature. Although non-limiting, the plasma treatment may include providing hydrogen (H₂) radicals or deuterium (D₂) radicals into the upper surface 106 of the SiC substrate, wherein the plasma dose may be constant or variable. Advantageously, H₂ and D₂ both passivate defects and dangling bonds in the device 100. More specifically, H₂ passivation of BPD and other defects minimizes growth and expansion of defects during device operation, thereby reducing SSF related device degradation.

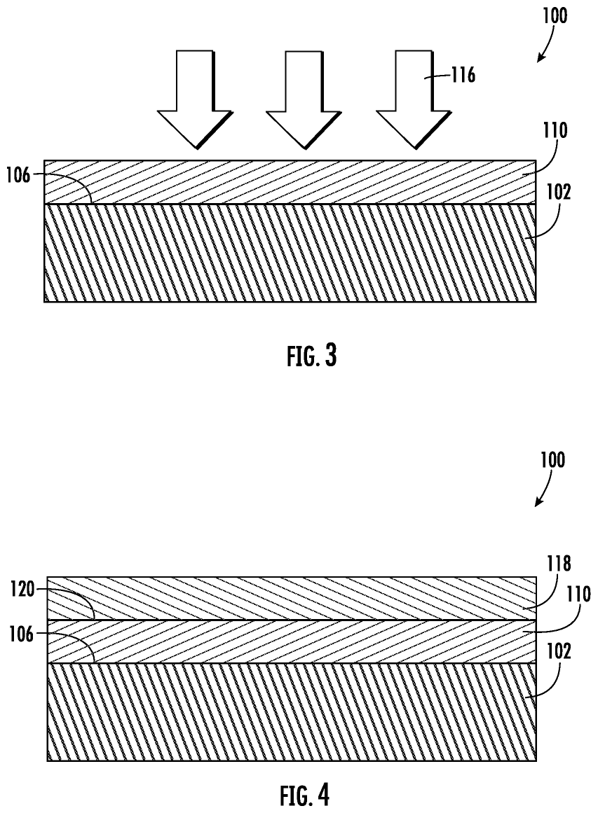

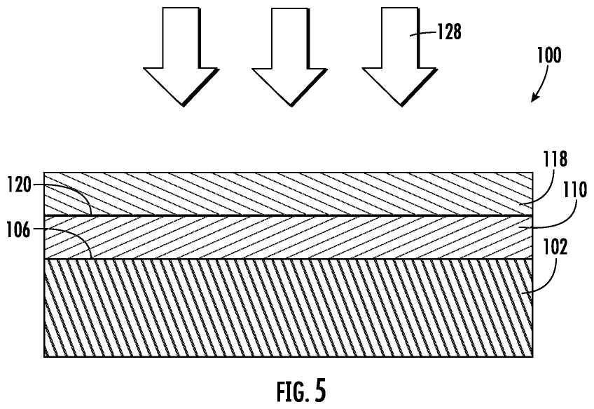

As shown in FIG. 2, a first epitaxial layer 110 may then be formed over the substrate 102. In some examples, the first epitaxial layer 110 may be a n⁻ layer, which is epitaxially grown directly atop the upper surface 106 of the substrate 102. As shown in FIG. 3, an optional second treatment 116 may then be performed, wherein the second treatment 116 is a beamline ion implant or a plasma doping process. As described above, the beam-line ion implant may include hydrogen ions delivered into the first epitaxial layer 110, while the plasma doping process may include hydrogen (H₂) or deuterium (D₂) radicals provided to the first epitaxial layer 110.

As shown in FIG. 4, a second epitaxial layer 118 may be formed over the first epitaxial layer 110. In some examples, the second epitaxial layer 118 may be a p+ layer, which is epitaxially grown directly atop an upper surface 120 of the first epitaxial layer 110. As shown in FIG. 5, an optional third treatment 128 may then be performed, wherein the third treatment is a beamline ion implant or a plasma doping process directed to the second epitaxial layer 118. Processing of the device 100 may then continue, e.g., by forming a device structure (not shown) over the second epitaxial layer 118.

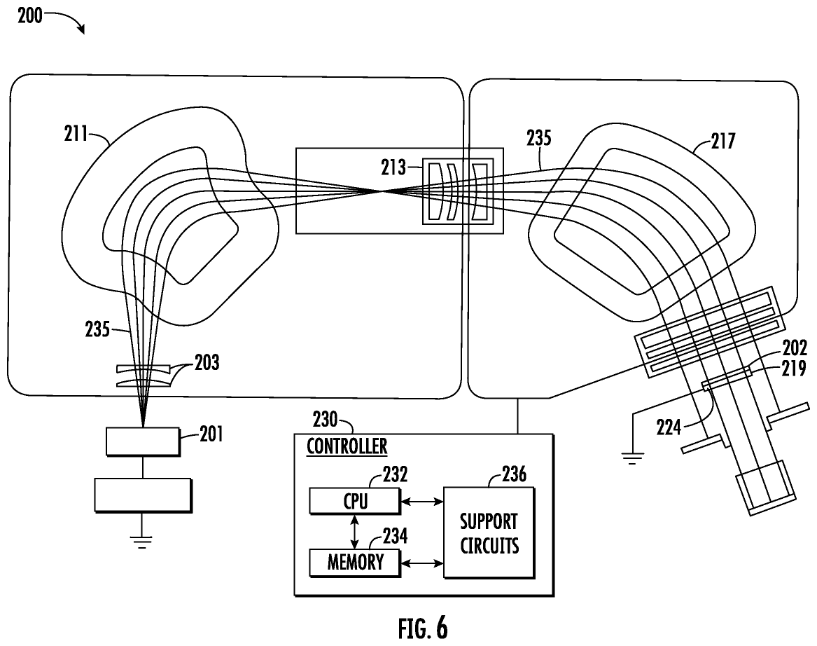

FIG. 6 illustrates a schematic diagram of a processing apparatus 200 useful to perform processes described herein. One example of a beam-line ion implantation processing apparatus is the Varian VIISTA® Trident, available from Applied Materials Inc., Santa Clara, CA. The processing apparatus 200 may include an ion source 201 for generating ions. For example, the ion source 201 may provide an ion implant, such as the ion implant of the first treatment process 104 demonstrated in FIG. 1 and/or the ion implant of the second treatment process 116 demonstrated in FIG. 3.

The processing apparatus 200 may also include a series of beam-line components. Examples of beam-line components may include extraction electrodes 203, a magnetic mass analyzer 211, a plurality of lenses 213, and a beam parallelize 217. The processing apparatus 200 may also include a platen 219 for supporting a substrate 202 to be processed. In some embodiments, the platen 219 may be heated using an external or embedded heating element 224, such as a resistive heater, or may be heated using radiant heat, such as heating lamps disposed above or below the platen 219. In other embodiments, the heating element may additionally, or alternatively, be located in a load lock chamber or a separate pre-heat chamber to pre-heat the wafer 202 before it reaches the platen 219. Even with a pre-heat, the platen 219 may include the internal heating element 224. The substrate 202 may be the same as the substrate 102 described above. The substrate 202 may be moved in one or more dimensions (e.g. translate, rotate, tilt, etc.) by a component sometimes referred to as a “roplat” (not shown). It is also contemplated that the processing apparatus 200 may be configured to perform heated implantation processes to provide for improved control of implantation characteristics, such as the ion trajectory and implantation energy utilized to dope the substrate.

In operation, ions of the desired species, for example, dopant ions, are generated and extracted from the ion source 201. Thereafter, the extracted ions 235 travel in a beam-like state along the beam-line components and may be implanted in the substrate 202. Similar to a series of optical lenses that manipulate a light beam, the beam-line components manipulate the extracted ions 235 along the ion beam. In such a manner, the extracted ions 235 are manipulated by the beam-line components while the extracted ions 235 are directed toward the substrate 202. It is contemplated that the apparatus 200 may provide for improved mass selection to implant desired ions while reducing the probability of undesirable ions (impurities) being implanted in the substrate 202.

In some embodiments, the processing apparatus 200 can be controlled by a processor-based system controller such as controller 230. For example, the controller 230 may be configured to control beam-line components and processing parameters associated with beam-line ion implantation processes. The controller 230 may include a programmable central processing unit (CPU) 232 that is operable with a memory 234 and a mass storage device, an input control unit, and a display unit (not shown), such as power supplies, clocks, cache, input/output (I/O) circuits, and the like, coupled to the various components of the processing apparatus 200 to facilitate control of the substrate processing. The controller 230 also includes hardware for monitoring substrate processing through sensors in the processing apparatus 200, including sensors monitoring the substrate position and sensors configured to receive feedback from and control a heating apparatus coupled to the processing apparatus 200. Other sensors that measure system parameters such as substrate temperature and the like, may also provide information to the controller 230.

To facilitate control of the processing apparatus 200 described above, the CPU 232 may be one of any form of general-purpose computer processor that can be used in an industrial setting, such as a programmable logic controller (PLC), for controlling various chambers and sub-processors. The memory 234 is coupled to the CPU 232 and the memory 234 is non-transitory and may be one or more of readily available memory such as random access memory (RAM), read only memory (ROM), floppy disk drive, hard disk, or any other form of digital storage, local or remote. Support circuits 236 may be coupled to the CPU 232 for supporting the processor in a conventional manner. Implantation and other processes are generally stored in the memory 234, typically as a software routine. The software routine may also be stored and/or executed by a second CPU (not shown) that is remotely located from the hardware being controlled by the CPU 232.

The memory 234 is in the form of computer-readable storage media that contains instructions, that when executed by the CPU 232, facilitates the operation of the apparatus 200. The instructions in the memory 234 are in the form of a program product such as a program that implements the method of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

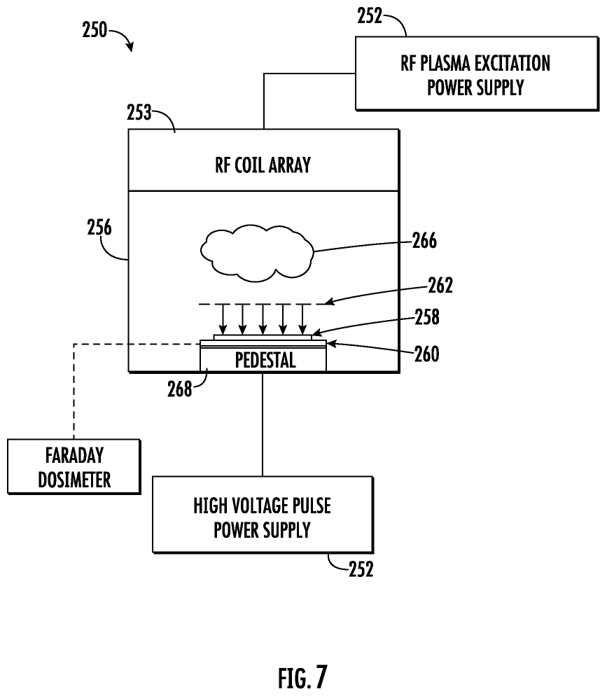

FIG. 7 demonstrates an example, non-limiting PLAD tool or system, which provides pulsed RF-excited continuous plasma doping. As shown, the system 250 may include a plasma power supply 251, a voltage pulse power supply 252, an RF coil array 253, and a dosimeter 254. Within a plasma chamber 256 is a wafer/substrate 258, which may be the same or similar to the substrate 102 described above. A platen/pedestal 260 may support the wafer 258, and a sheath 262 may be formed above the wafer 258. The dosimeter 254 may be a Faraday dosimeter or other type of sensor that directly measures the dose of ions received by the wafer 258. Although non-limiting, the dosimeter can be located on the pedestal 260, proximate to the wafer 258.

During use, the plasma power supply 252 and the RF coil array 253 deliver radio frequency excitation to generate a plasma 266 when gaseous species are delivered into the plasma chamber 256. For example, the plasma power supply 251 may be an RF powered inductively coupled power source to generate inductively coupled plasma 266, as known in the art. Gaseous species may be delivered from one or more gas sources (not separately shown) to generate radicals of any suitable species, such as H₂ and D₂.

The voltage pulse power supply 252 may generate a bias voltage between the wafer 258 and the plasma chamber 256. As such, when the voltage pulse power supply 252 generates a voltage between the plasma chamber 256 and the substrate 258, a similar, but slightly larger, voltage difference is generated between the plasma 266 and the substrate 258. In one non-limiting example, a 5000 (5 kV) voltage difference established between the plasma chamber 256 and the substrate 258 (or, equivalently, pedestal 214) may generate a voltage difference of approximately 5005 V to 5030 V between the plasma 266 and the substrate 258.

In some embodiments, the voltage pulse power supply 252 may generate a bias voltage as a pulsed voltage signal, wherein the pulsed voltage signal is applied in a repetitive and regular manner, to generate a pulse routine comprising a plurality of extraction voltage pulses. For example, a pulse routine may apply voltage pulses of 500 V magnitude, 1000 V magnitude, 2000 V magnitude, 5000 V magnitude, or 10,000 V magnitude in various non-limiting embodiments. The system 250 may further include a controller (not shown), to control the pulsing routine applied to the substrate 258.

According to various embodiments, the plasma 266 may be formed at least in part of ions that constitute an amorphizing species, wherein the amorphizing species may be any suitable ion capable of amorphizing an initially crystalline region of materials, such as the substrate 258. When the plasma 266 is present in the plasma chamber 256, the controller may generate a signal for the voltage pulse power supply 252 to apply a pulse routine to the substrate 258, where the pulse routine constitutes a plurality of extraction voltage pulses. As such, when the extraction voltage pulses are applied between the substrate 258 and plasma 266, ions are extracted in pulsed form from the plasma 266, generating a plurality of ion pulses that are directed to the substrate 258.

In some embodiments, the platen/pedestal 260 may include an external or internal heating element 268, such as a resistive heater, or may be heated using radiant heat, such as heating lamps disposed above or below the platen/pedestal 260. In other embodiments, the heating element 268 may additionally, or alternatively, be located in a load lock chamber or a separate pre-heat chamber to pre-heat the wafer 202 before it reaches the platen/pedestal 260.

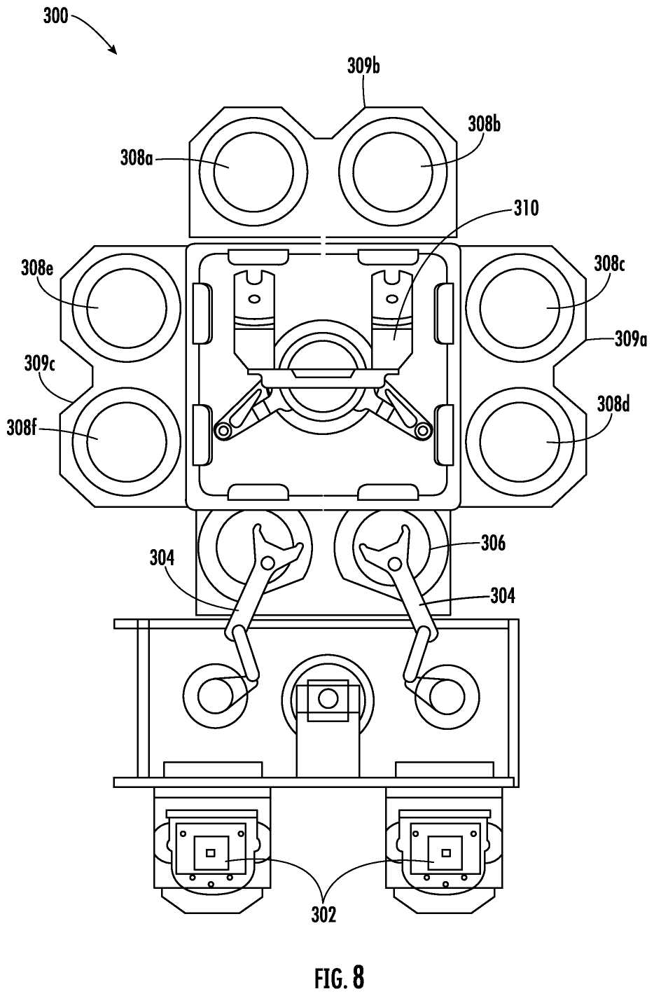

FIG. 8 illustrates a top plan view of one embodiment of another processing system 300 including a plurality of chambers according to some embodiments. As shown, a pair of front opening unified pods 302 supply substrates of a variety of sizes that are received by robotic arms 304 and placed into a low-pressure holding area 306 before being placed into one of the substrate processing chambers 308a-f, positioned in tandem sections 309a-c. A second robotic arm 310 may be used to transport the substrate wafers from the holding area 306 to the substrate processing chambers 308a-f and back. Each substrate processing chamber, 308a-f, can be outfitted to perform a number of substrate processing operations described herein such as ion implant, pre-clean, anneal, plasma processing, degas, orientation, and other substrate processes.

The substrate processing chambers 308a-f may include one or more system components for depositing, treating, growing, annealing, curing, implanting, and/or etching the substrate and/or a material layer on the substrate or wafer. In one configuration, two pairs of the processing chambers, for example 308a-b, may be used treat the substrate and/or the material layers formed atop the substrate using a beamline ion implant. Another two pairs of the processing chambers, for example, 308c-d, may be used to treat the substrate and/or the material layers formed atop the substrate using a plasma doping (PLAD) process. In some embodiments, the PLAD process may be performed in a pre-clean chamber. Another two pairs of the processing chambers, for example, 308e-f, may be used to epitaxially grow material on the substrate. More specifically, processing chambers 308e-f may be configured as a selective epitaxial growth chamber for performing one or more different epitaxial growth processes. In another configuration, all three pairs of chambers, for example 308a-f, may be configured to epitaxially grow material and treat the substrate/material on the substrate.

Any one or more of the processes described may be carried out in additional chambers separated from the fabrication system shown in different embodiments. It will be appreciated that additional configurations of deposition, treating, growing, etching, annealing, and curing chambers for substrates and material layers are contemplated by the processing system 300. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

The processing system 300, or more specifically, chambers incorporated into the processing system 300 or other processing systems, may be used to produce structures according to some embodiments of the present disclosure.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
providing a silicon carbide (SiC) substrate;
treating the SiC substrate using an ion implant or a plasma doping process;
forming a first epitaxial layer over an upper surface of the SiC substrate after the SiC substrate is treated; and
forming a second epitaxial layer over the first epitaxial layer.

2. The method of claim 1, further comprising treating the first epitaxial layer using a second ion implant or a second plasma doping process.

3. The method of claim 1, wherein the ion implant comprises delivering hydrogen ions into the upper surface of the SiC substrate.

4. The method of claim 3, wherein the hydrogen ions are delivered while the substrate is at a temperature between 15-40° C.

5. The method of claim 3, wherein the hydrogen ions are delivered while the substrate is at a temperature greater than 40° C.

6. The method of claim 1, wherein the plasma doping process comprises providing hydrogen radicals or deuterium radicals into the upper surface of the SiC substrate.

7. The method of claim 6, wherein the hydrogen or deuterium radicals are provided while the substrate is at a temperature between 15-40° C.

8. The method of claim 6, wherein the hydrogen or deuterium radicals are provided while the substrate is at a temperature greater than 40° C.

9. The method of claim 1, wherein the SiC substrate is a n⁺ layer, wherein the first epitaxial layer is a n layer, and wherein the second epitaxial layer is a p⁺ layer.

10. The method of claim 1, wherein the second epitaxial layer is formed prior to formation of a device structure.

11. A method of forming a silicon carbide (SiC) device, the method comprising:
providing a SiC substrate;
treating the SiC substrate using an ion implant or a plasma doping process;
epitaxially forming a n layer over an upper surface of the SiC substrate after the SiC substrate is treated; and
epitaxially forming a p+ layer over the n layer.

12. The method of claim 11, further comprising performing, after the n⁻ layer is epitaxially formed, a second ion implant or a second plasma doping process.

13. The method of claim 11, wherein the ion implant comprises delivering hydrogen ions into the upper surface of the SiC substrate.

14. The method of claim 13, wherein the hydrogen ions are delivered at a temperature greater than 15 C.

15. The method of claim 11, wherein the plasma doping process comprises providing hydrogen radicals or deuterium radicals into the upper surface of the SiC substrate.

16. The method of claim 15, wherein the hydrogen radicals or deuterium radicals are provided at a temperature greater than 15° C.

17. The method of claim 11, wherein the SiC substrate is a n⁺ layer.

18. A system for forming a silicon carbide (SiC) device, the system comprising:
a first processing chamber comprising at least one of: an ion implanter operable to treat a SiC substrate by performing an ion implant, and a plasma doping tool operable to treat the SiC substrate by performing a plasma doping process; and
a second processing chamber operable to:
epitaxially form a n layer over an upper surface of the SiC substrate after the SiC substrate is treated; and
epitaxially form a p+ layer over the n⁻ layer.

19. The system of claim 18, wherein the first processing chamber is further operable to perform, after the n⁻ layer is epitaxially formed, a second ion implant or a second plasma doping process.

20. The system of claim 18, wherein the ion implanter is operable to deliver hydrogen ions or deuterium ions into the upper surface of the SiC substrate, and wherein the plasma doping tool is operable to provide hydrogen radicals or deuterium radicals into the upper surface of the SiC substrate.
